(19) United States
(12) Patent Application Publication
(10) Pub. No.: US 2007/0103211 A1
(43) Pub. Date: May 10, 2007

(54) RESET CIRCUIT

(75) Inventor: MING-CHIH HSIEH, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,761

(22) Filed: Sep. 22, 2006

(30) Foreign Application Priority Data
Nov. 4, 2005 (CN) 200510101021.3

(51) Int. Cl. H03L 7/00

(52) U.S. Cl. 327/143

(57) ABSTRACT

An exemplary reset circuit includes a reset signal generator providing a first reset signal, an inverter, and a NAND gate. The inverter includes an input connected to the reset signal generator for receiving the first reset signal, and an output. The NAND gate includes a first input connected to the output of the inverter, a second input connected to a control terminal receiving a control signal, and an output. The reset circuit delivers a second reset signal at the output of the NAND gate in according to the first reset signal and the control signal. The reset circuit protects a system from accidental reset.

### CROSS-REFERENCE TO RELATED APPLICATION

Related subject matter is disclosed in a co-pending U.S. Patent Application entitled “RESET CIRCUIT,”(attorney docket number: US9119) which is assigned to the same assignee as that of the present application.

### 1. FIELD OF THE INVENTION

The present invention relates to a reset circuit, and particularly to an improved reset circuit protecting computer system from an undesired reset.

### 2. DESCRIPTION OF RELATED ART

Reset circuits for resetting the state of a circuit system to an original state, and the operation of a conventional reset circuit, are illustrated in FIG. 2. Referring to FIG. 2, the conventional reset circuit comprises a resistor R′, a diode D′, a capacitor C′, and a reset button S′. The resistor R′ and the reset button S′ are connected between a power supply source Vcc and ground in series. The diode D′ and the capacitor C′ are connected between the power supply source Vcc and ground in series with a cathode of the diode D′ connected to the power supply source Vcc and an anode of the diode D′ connected to the capacitor C′. A node between the diode D′ and the capacitor C′ is connected to a node between the resistor R′ and the reset button S′. The node between the resistor R′ and the reset button S′ acts as a reset signal output terminal A′. During normal operation, the voltage at the output terminal A′ is at a high level. When the reset button S′ is pressed, the voltage at the output terminal A′ goes to a low level, and a reset signal is output from the power circuit for resetting the system. However, if the reset button is inadvertently pressed, an undesired reset of the system occurs, and the system may experience data damage, data loss, file corruption, or hardware damage. It is apparent that the system does not provide adequate protection against such occurrences.

What is needed is to provide an improved reset circuit which provides adequate protection against accidental reset.

### SUMMARY OF THE INVENTION

An exemplary reset circuit includes a reset signal generator providing a first reset signal, an inverter, and a NAND gate. The inverter includes an input connected to the reset signal generator for receiving the first reset signal, and an output. The NAND gate includes a first input connected to the output of the inverter, a second input connected to a control terminal receiving a control signal, and an output. The reset circuit delivers a second reset signal at the output of the NAND gate in accordance with the first reset signal and the control signal.

Other advantages and novel features of the invention will become more apparent from the following detailed description when taken in conjunction with the accompanying drawings, in which:

### BRIEF DESCRIPTION OF THE DRAWINGS

FIG. 1 is a circuit diagram of a reset circuit in accordance with a preferred embodiment of the present invention; and

FIG. 2 is a circuit diagram of a conventional reset circuit.

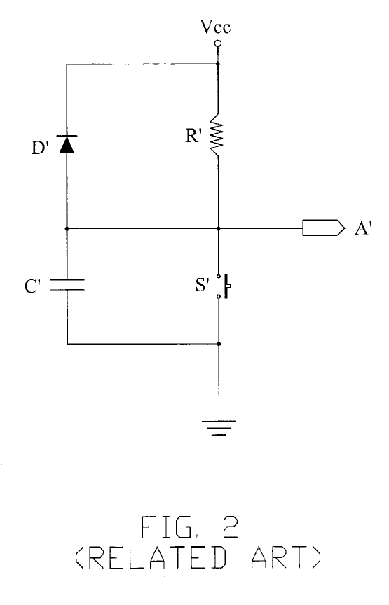

### DETAILED DESCRIPTION OF THE INVENTION

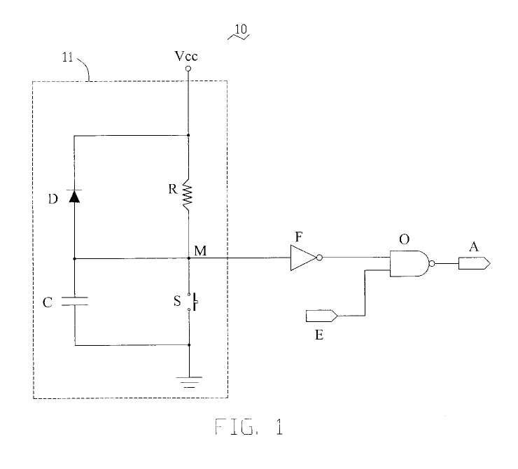

Referring to FIG. 1, a reset circuit 10 in accordance with a preferred embodiment of the present invention includes a reset signal generator 11, an inverter F, a NAND gate O, and a control terminal E.

The reset signal generator 11 includes a resistor R, a diode D, a capacitor C, and a reset button S. The resistor R and the reset button S are connected between a power supply source Vcc and ground in series. The diode D and the capacitor C are connected between the power supply source Vcc and ground in series with a cathode of the diode D connected to the power supply source Vcc and an anode of the diode D connected to the capacitor C. A node between the diode D and the capacitor C is connected to a node M between the resistor R and the reset button S. The node M acts as a first reset signal output terminal. An input of the inverter F is coupled to the node M, and an output of the inverter F is coupled to a first input of the NAND gate O. The control terminal E is connected to a second input of the NAND gate O. An output of the NAND gate O acts as an output A of the reset circuit 10, and is connected to a reset signal receiver of the computer.

In operation, if a system utilizing the reset circuit 10 need not be reset, the voltage at the control terminal E is set at a low level by a user command at a terminal of the system, the voltage at the output A of the reset circuit 10 is always at a high level, and the system can not be reset, even if the reset button S is pushed.

If the system needs to be reset, the voltage at the control terminal E is set at a high level by the user command at a terminal of the system. When the reset button S is in a normal position (i.e. not pressed down), the voltage at the node M is at a high level, the inverter E inverts the high level at the node M to a low level, and the voltage at the output A of the reset circuit 10 is at a high level, thus the system works normally. If the reset button S is pressed down, and the first reset signal is at a low level, the low voltage at the node M is inverted into a high level by the inverter F, the voltage at the output A of the reset circuit 10 is at a low level, and a second reset signal is output from the output A of the reset circuit 120 for resetting the system.

According to the above embodiment, an enable control signal is input to the control terminal E of the reset circuit 10 when the system is to be reset, and the reset signal generator 11 outputs a first reset signal, a second reset signal is output from the reset circuit 10 for resetting the system in accordance with the first reset signal. When the system need not be reset, the control signal at the control terminal E is disabled, therefore the system can not be reset even if the first reset signal is received. Thus the reset circuit 10 protects the system from an accidental reset.

It is believed that the present embodiment and its advantages will be understood from the foregoing description, and it will be apparent that various changes may be made thereto without departing from the spirit and scope of the invention or sacrificing all of its material advantages, the example hereinbefore described merely being preferred or exemplary embodiment of the invention.

What is claimed is:

1. A reset circuit, comprising:
a reset signal generator providing a first reset signal;
an inverter comprising an input connected to the reset signal generator for receiving the first reset signal, and an output; and
a NAND gate having a first input connected to the output of the inverter, a second input connected to a control terminal receiving a control signal, and an output, the reset circuit delivering a second reset signal at the output of the NAND gate in according to the first reset signal and the control signal.

2. The reset circuit as claimed in claim 1, wherein the reset signal generator comprises a resistor, a diode, a capacitor, and a reset button, the resistor and the reset button are connected between a power supply source and ground in series, the diode and the capacitor are connected between the power supply source and ground in series with a cathode of the diode connected to the power supply source and an anode of the diode connected to the capacitor, a node between the diode and the capacitor is connected to a node between the resistor and the reset button.

3. A reset circuit, comprising:
a reset signal generator comprising an output; and
a logic circuit connected to the output of the reset signal generator and a control terminal, when a control signal at the control terminal is enabled and a signal at the output of the reset signal generator is enabled, an enable reset signal is output from the logic circuit for resetting a computer system; when the control signal at the control terminal is disabled, the system can not be reset.

4. The reset circuit as claimed in claim 3, wherein the logic circuit comprises an inverter and a NAND gate, an input of the inverter is connected to the output of the signal generator, an output of the inverter is connected to a first input of the NAND gate, the control terminal is connected to a second input of the NAND gate, the reset signal is output from an output of the NAND gate.
